(19) United States
(12) Patent Application Publication
(10) Pub. No.: US 2026/0005143 A1
(43) Pub. Date: Jan. 1, 2026

(54) SEMICONDUCTOR DEVICE HAVING A POWER DISTRIBUTION LAYER

(71) Applicant: SK hynix Inc., Gyeonggi-do (KR)

(72) Inventor: Jin Kyeong SEONG, Gyeonggi-do (KR)

(21) Appl. No.: 19/055,502

(22) Filed: Feb. 18, 2025

(30) Foreign Application Priority Data
Jul. 1, 2024 (KR) 10-2024-0086050

(51) Int. Cl. H01L 23/528

(52) U.S. Cl. CPC H01L 23/5286; H01L 23/5283

(57) ABSTRACT

A semiconductor device includes transistors disposed on a substrate; and interconnection layers disposed over the transistors. The interconnection layers include a lower interconnection layer and an upper interconnection layer disposed over the lower interconnection layer. The upper interconnection layer includes first patterns extending in parallel in a first direction; and second patterns disposed between the first patterns, and connecting the first patterns to each other in a second direction perpendicular to the first direction. The second patterns are arranged spaced apart from each other in the first direction, and arranged in a zigzag shape in the second direction.

### CROSS-REFERENCE TO RELATED APPLICATIONS

The present application claims priority under 35 U.S.C. 119 (a) to Korean Patent Application No. 10-2024-0086050, filed on Jul. 1, 2024, which is incorporated herein by reference in its entirety.

### BACKGROUND

### 1. Field

Embodiments of the present disclosure relate to a semiconductor device having a power distribution layer.

### 2. Description of the Related Art

Uniform power supply and signal transmission are important factors necessary for stable operation of a semiconductor device. It is required to remove defective elements in metal interconnections for uniform power supply and signal transmission.

### SUMMARY

Embodiments of the present disclosure provide designs or structures of a metal interconnection layer configured to reduce defect elements.

Embodiments of the present disclosure provide semiconductor devices having metal interconnection layers with reduced defect elements.

Embodiments of the present disclosure provide semiconductor devices having a power distribution network having geometric patterns arranged in parallel in a first direction and offset in a second direction.

In accordance with another embodiment of the present disclosure, a semiconductor device includes transistors disposed on a substrate; and interconnection layers disposed over the transistors. The interconnection layers include a lower interconnection layer and an upper interconnection layer disposed over the lower interconnection layer. The upper interconnection layer includes first patterns extending in parallel in a first direction; and second patterns disposed between the first patterns, and connecting the first patterns to each other in a second direction perpendicular to the first direction. The second patterns are arranged spaced apart from each other in the first direction and arranged in a zigzag shape in the second direction.

In accordance with another embodiment of the present disclosure, a semiconductor device includes a lower interconnection layer including a plurality of lower interconnections; a middle interconnection layer disposed on the lower interconnection layer, and including a plurality of middle interconnections; and a power distribution network on the middle interconnection layer. The power distribution network includes a plurality of line patterns extending in parallel in a first direction; and a plurality of first segment patterns having an elongated shape in a second direction perpendicular to the first direction. Each of the first segment patterns contacts two of the line patterns adjacent in the second direction. The first segment patterns are disposed spaced apart from each other in the first direction.

In accordance with another embodiment of the present disclosure, a semiconductor device includes a plurality of line patterns extending in parallel in a first direction; and a plurality of segment patterns between the plurality of line patterns, and connecting two adjacent line patterns of the line patterns to each other in a second direction. The first direction is perpendicular to the second direction. The plurality of line patterns and the plurality of segment patterns are arranged to form a plurality of geometric patterns so that two adjacent line patterns of the plurality of line patterns and two adjacent segment patterns of the plurality of segment patterns in the first direction form one geometric pattern. The geometric patterns are aligned in the first direction and arranged side-by-side. The geometric patterns are arranged offset in the second direction.

### BRIEF DESCRIPTION OF THE DRAWINGS

FIG. 1 is a schematic longitudinal cross-sectional view of a semiconductor device in accordance with an embodiment of the present disclosure.

FIGS. 2A to 2C are schematic top views of upper interconnection layers in accordance with embodiments of the present disclosure.

FIGS. 3A, 3B, 4A, 4B, 5A and 5B are views for describing a method of forming an interconnection structure according to an embodiment of the present disclosure.

FIG. 6A is a plan view illustrating grid-type conventional trenches formed by conventional technology, and FIG. 6B is a longitudinal cross-sectional view taken along the line IV-IV′ of FIG. 6A.

FIG. 7A is a plan view illustrating conventional interconnection patterns formed by conventional technology, and FIG. 7B is a longitudinal cross-sectional view taken along the V-V′ line of FIG. 7A.

### DETAILED DESCRIPTION

Various embodiments of the present disclosure will be described below in more detail with reference to the accompanying drawings. The embodiments may, however, be embodied in different forms and should not be construed as limited to the embodiments set forth herein. Rather, these embodiments are provided so that this disclosure will be thorough and complete, and will fully convey the scope of the present disclosure to those skilled in the art. Throughout this disclosure, like reference numerals refer to like parts throughout the various figures and embodiments of the present disclosure.

Hereinafter, the various embodiments of the present disclosure will be described in detail with reference to the attached drawings.

The drawings are not necessarily to scale and in some instances, proportions may have been exaggerated to clearly illustrate features of the embodiments. When a first layer is referred to as being “on” a second layer or “on” a substrate, it not only refers to a case where the first layer is formed directly on the second layer or the substrate but also a case where a third layer exists between the first layer and the second layer or the substrate.

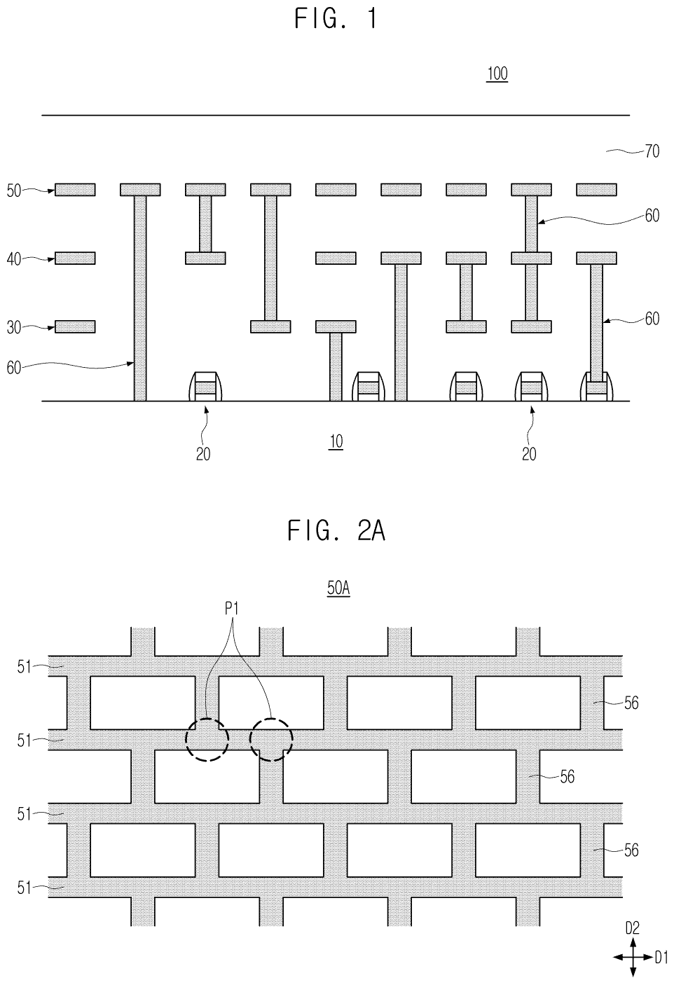

FIG. 1 is a schematic longitudinal cross-sectional view of a semiconductor device 100 in accordance with an embodiment of the present disclosure. Referring to FIG. 1, the semiconductor device 100 may include transistors 20, horizontal interconnection layers 30, 40, and 50, and vertical via plugs 60. The transistors 20, the horizontal interconnection layers 30, 40, and 50, and the vertical via plugs 60 may be disposed on a substrate 10 including a silicon layer such as a semiconductor wafer. The transistors 20, the horizontal interconnection layers 30, 40, and 50, and the vertical via plugs 60 may be surrounded or covered by an insulating layer 70. The insulating layer 70 may include at least one of silicon oxide-based insulating materials or silicon nitride-based insulating materials.

The horizontal interconnection layers 30, 40, and 50 may transmit electrical signals in a horizontal direction. The horizontal interconnection layers 30, 40, and 50 may include at least three layers. For example, the horizontal interconnection layers 30, 40, and 50 may include a lower interconnection layer 30, a middle interconnection layer 40, and an upper interconnection layer 50. The lower interconnection layer 30 may be disposed over the transistors 20 and may include a plurality of lower horizontal interconnections. The middle interconnection layer 40 may be disposed over the lower interconnection layer 30 and may include a plurality of middle horizontal interconnections. The upper interconnection layer 50 may be disposed over the middle interconnection layer 40 and may include a plurality of upper horizontal interconnections. The lower interconnection layer 30 and the middle interconnection layer 40 may transmit a command signal, a data signal, a clock signal, and other electrical signals. The upper interconnection layer 50 may transmit power. For example, the upper interconnection layer 50 may be a power interconnection layer. In an embodiment, the upper interconnection layer 50 may be a power distribution network (PDN).

The vertical via plugs 60 may transmit electrical signals in a vertical direction. The vertical via plugs 60 may selectively and electrically connect the substrate 10, some of the lower interconnections of the lower interconnection layer 30, some of the middle interconnections of the middle interconnection layer 40, and some of the upper interconnections of the upper interconnection layer 50 to each other. Therefore, some of the upper interconnections of the upper interconnection layer 50 may be selectively and electrically connected to some of the middle interconnections of the middle interconnection layer 40, some of the lower interconnections of the lower interconnection layer 30, some of the transistors 20, and the substrate 10.

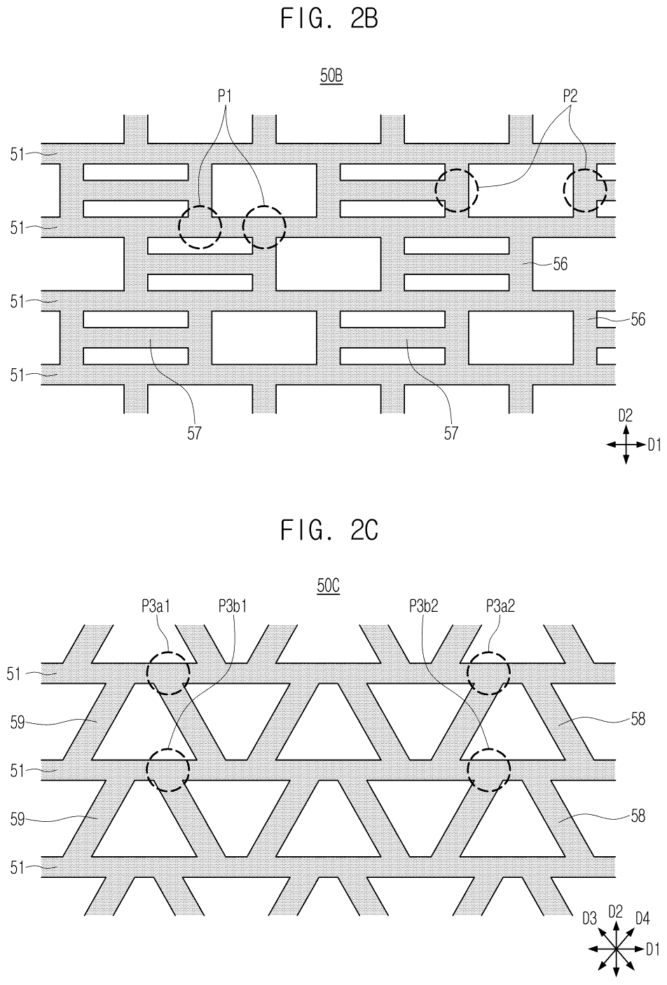

FIGS. 2A to 2C are schematic top views of upper interconnection layers 50A, 50B and 50C in accordance with embodiments of the present disclosure. Each of the upper interconnection layers 50A, 50B, and 50C may correspond to the upper interconnection layer 50 of FIG. 1.

Referring to FIG. 2A, the upper interconnection layer 50A may include line patterns 51 and first segment patterns 56. The line patterns 51 may extend in parallel with each other in a first direction D1. Each of the first segment patterns 56 may be disposed between the two adjacent line patterns 51 to connect the two adjacent line patterns 51 to each other in a second direction D2. The first direction D1 and the second direction D2 may be perpendicular with each other. In another embodiment, the first direction D1 and the second direction D2 may cross each other in a diagonal direction.

Each of the first segment patterns 56 may have one of a segment shape, a bar shape, or a bridge shape that is elongated in the second direction D2. The first segment patterns 56 may be arranged spaced apart from each other in the first direction D1. The first segment patterns 56 may be offset arranged in the second direction D2. For example, the first segment patterns 56 may not be aligned with each other in the second direction D2. In an embodiment, the first segment patterns 56 may be arranged in a zigzag form in the second direction D2. The upper interconnection layer 50A may have a rail shape or a ladder shape extending in the first direction D1. Two adjacent line patterns 51 and two adjacent first segment patterns 56 may form a geometric pattern. The geometric pattern may include a square pattern. Accordingly, the upper interconnection layer 50A may be a structure having the square patterns arranged continuously side-by-side in the first direction D1, and having the square patterns arranged offset in the second direction D2. For example, the upper interconnection layer 50A may have an offset square grid pattern structure.

The upper interconnection layer 50A may include first connection points P1 to connect the line patterns 51 to the first segment patterns 56. For example, at one of the first connection points P1, one end of the first segment patterns 56 may be contacted and connected to one side of the line patterns 51. At each of the first connection points P1, each of the line patterns 51 and each of the first segment patterns 56 may form a right angle. The first connection points P1 may have a T-shaped branch point structure or a reversed T-shaped branch point structure.

Referring to FIG. 2B, the upper interconnection layer 50B may include line patterns 51, first segment patterns 56, and second segment patterns 57. Compared with the upper interconnection layer 50A described with reference to FIG. 2A, the upper interconnection layer 50B may further include the second segment patterns 57. Each of the second segment patterns 57 may be disposed between the two adjacent line patterns 51 in the second direction D2, and between the two adjacent first segment patterns 56 in the first direction D1. The second segment patterns 57 may connect two adjacent first segment patterns 56 to each other in the first direction D1. Each of the second segment patterns 57 may have at least one of a segment shape, a bar shape, or a bridge shape that is elongated in the first direction D1.

The upper interconnection layer 50B may include first connection points P1 and second connection points P2. Compared with the upper interconnection layer 50A described with reference to FIG. 2A, the upper interconnection layer 50B may further include second connection points P2. Each of the second connection points P2 may be a point at which one of the first segment patterns 56 and one of the second segment patterns 57 are connected to each other. For example, at one of the second connection points P2, one end of the second segment patterns 57 may be contacted and connected to one side of the first segment patterns 56. At one of the second connection points P2, each of the first segments 56 and each of the second segments 57 may form a right angle. Accordingly, each of the first connection points P1 and each of the second connection points P2 may have a T-shaped branch point structure, a reversed T-shaped branch point structure, or a rotated T-shaped branch point structure.

Referring to FIG. 2C, the upper interconnection layer 50C may include line patterns 51, first diagonal segment patterns 58, and second diagonal segment patterns 59. Each of the first diagonal segment patterns 58 may have a segment shape, a bar shape, or a bridge shape that is elongated in the first diagonal direction D3. The first diagonal direction D3 may diagonally cross the first direction D1 and the second direction D2. Each of the second diagonal segment patterns 59 may have a segment shape, a bar shape, or a bridge shape that is stretched in a second diagonal direction D4. The second diagonal direction D4 may diagonally cross the first direction D1 and the second direction D2. The first diagonal direction D3 and the second diagonal direction D4 may not be perpendicular to each other. In an embodiment, the first diagonal segments 58 and the second diagonal segments 59 may have a symmetrical (mirrored) shape and a symmetrical (mirrored) arrangement in the first direction D1. Two adjacent (a pair of) line patterns 51 and two adjacent (a pair of) diagonal segment patterns 58 and 59 may form a geometric pattern. In an embodiment, the geometric pattern may include a triangular pattern or a trapezoidal pattern. The upper interconnection layer 50B may have a triangular pattern and a reversed triangular pattern alternating arrangement, or a trapezoidal pattern and a reversed trapezoidal pattern alternating arrangement in the first direction D1. The geometric patterns may be repeatedly arranged in the second direction D2. The upper interconnection layer 50B may have a continuous (or parallel) arrangement in the second direction D2 with the triangular patterns or the reversed triangular patterns, or the trapezoidal patterns or the reversed trapezoidal patterns.

The upper interconnection layer 50C may have diagonal connection points P3a1, P3a2, P3b1, and P3b2. The diagonal connection points P3a1, P3a2, P3b1, and P3b2 may include first upper diagonal connection points P3a1, first lower diagonal connection points P3a2, second upper diagonal connection points P3b1, and second lower diagonal connection points P3b2. Each of the first upper diagonal connection points P3a1 may be a connection point where a lower surface of each of the line patterns 51 contacts an upper end of each of the first diagonal segment patterns 58. Each of the first lower diagonal connection points P3a2 may be a connection point where an upper surface of each of the line patterns 51 contacts a lower end of each of the first diagonal segment patterns 58. Each of the second upper diagonal connection points P3b1 may be a connection point where a lower surface of each of the line patterns 51 contacts an upper end of each of the second diagonal segment patterns 59. Each of the second lower diagonal connection points P3b2 may be a connection point where an upper surface of each of the line patterns 51 contacts a lower end of each of the second diagonal segment patterns 59. Each of the diagonal connection points P3a1, P3a2, P3b1, and P3b2 may be a connection point where one of the line patterns 51 contacts one end of each of the diagonal segment patterns 58 and 59. At the diagonal connection points P3a1, P3a2, P3b1, and P3b2, each of the line patterns 51 and each of the diagonal segment patterns 58 and 59 may not form a right angle. For example, at the diagonal connection points P3a1, P3a2, P3b1, and P3b2, each of the line patterns 51 and each of the diagonal segment patterns 58 and 59 may form one of an acute angle or an obtuse angle. The diagonal connection points P3a1, P3a2, P3b1, and P3b2 may have a n-shaped connection structure, a Y-shaped connection structure, or a rotated K-shaped connection structure. In another embodiment, one of the first diagonal segment patterns 58 or the second diagonal segment patterns 59 may be omitted.

In the upper interconnections 50A, 50B, and 50C described with reference to FIGS. 2A to 2C, the line patterns 51 and the segment patterns 56-59 may be connected to contact each other without crossing. Specifically, at the connection points P1, P2, P3a1, P3a2, P3b1, and P3b2, one end of each of the segment patterns 56-59 may contact one side of each of the line patterns 51.

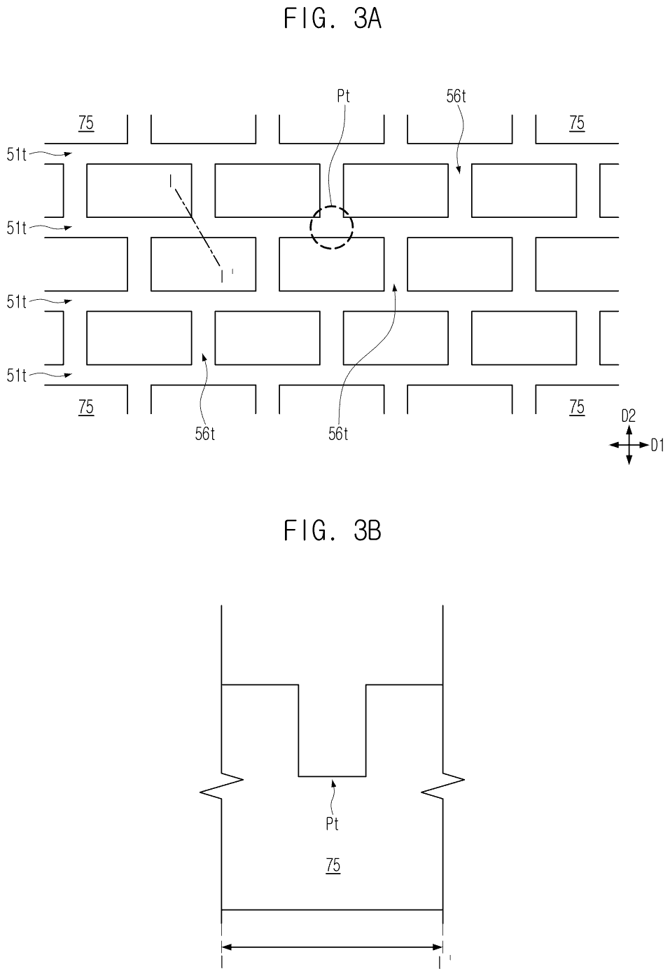

FIGS. 3A, 3B, 4A, 4B, 5A and 5B are views for describing a method of forming an interconnection structure according to an embodiment of the present disclosure. FIGS. 3A, 4A, and 5A are plan views of an interconnection structure, and FIGS. 3B, 4B, and 5B are longitudinal cross-sectional views taken along lines I-I′, II-II′ and III-III′ of the corresponding plan views, respectively. The interconnection structure may correspond to the upper interconnection layer 50 of FIG. 1, and may be one of the upper interconnection layers 50A-50C of FIGS. 2A to 2C. In some embodiments, the interconnection structure may be a power interconnection structure. That is, the interconnection structure may be a power distribution network (PDN).

Referring to FIGS. 3A and 3B, a method of forming the interconnection structure may include forming trenches 51t and 56t in an upper portion of an underlying layer 75. The trenches 51t and 56t may include line trenches 51t extending in parallel in a first direction D1 and segment trenches 56t connecting the line trenches 51t in a second direction D2. Trench branch points Pt, to which the line trenches 51t and the segment trenches 56t are connected, may be formed. The segment trenches 56t may have a shape of segments extending in the second direction D2. The underlying layer 75 may include an insulating layer such as a silicon oxide layer or a silicon nitride layer. In an embodiment, the underlying layer 75 may include a doped silicon layer including dopants.

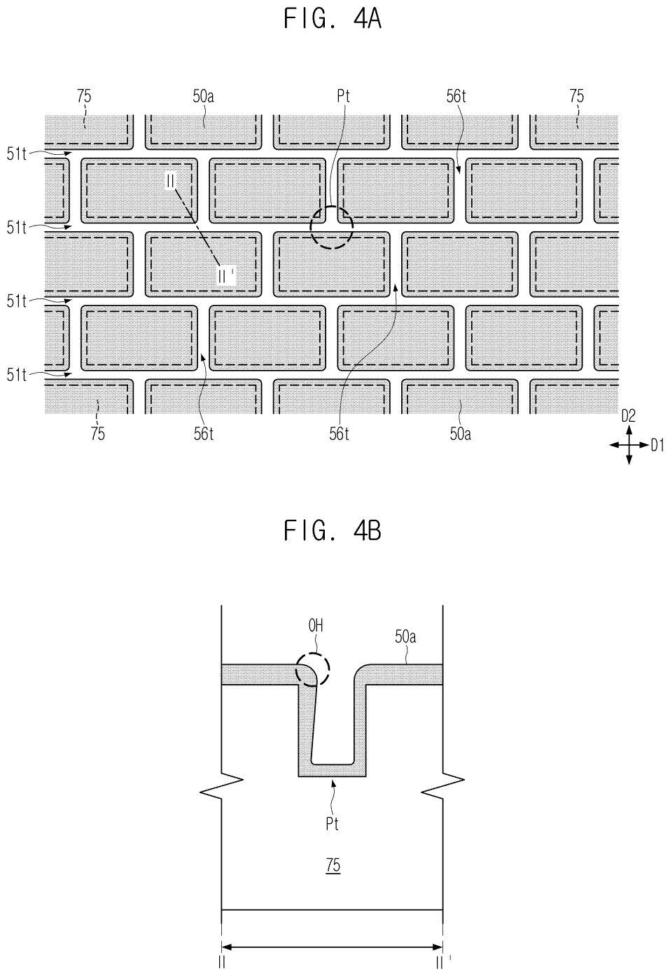

Referring to FIGS. 4A and 4B, the method may include forming an initial interconnection material layer 50a by performing an initial deposition process. The initial interconnection material layer 50a may cover an upper surface of the underlying layer 75 and may partially fill the inside of the trenches 51t and 56t. For example, the initial interconnection material layer 50a may be conformally formed on inner walls and bottom surfaces of the trenches 51t and 56t. In the trenches 51t and 56t, the initial interconnection material layer 50a may have an asymmetric deposited structure. Specifically, an overhang OH may occur on the sidewalls of the underlying layer 75 corresponding to a corner to which the first trench 51t and the second trench 56t are connected, but may not occur on the sidewalls of the underlying layer 75 corresponding to sidewalls of the first trench 51t or the second trench 56t. In an embodiment, the overhang OH may heavily occur on the sidewalls of the underlying layer 75 corresponding to the corner to which the first trench 51t and the second trench 56t are connected, but may lightly occur on the sidewalls of the underlying layer 75 corresponding to the side of the first trench 51t or the second trench 56t.

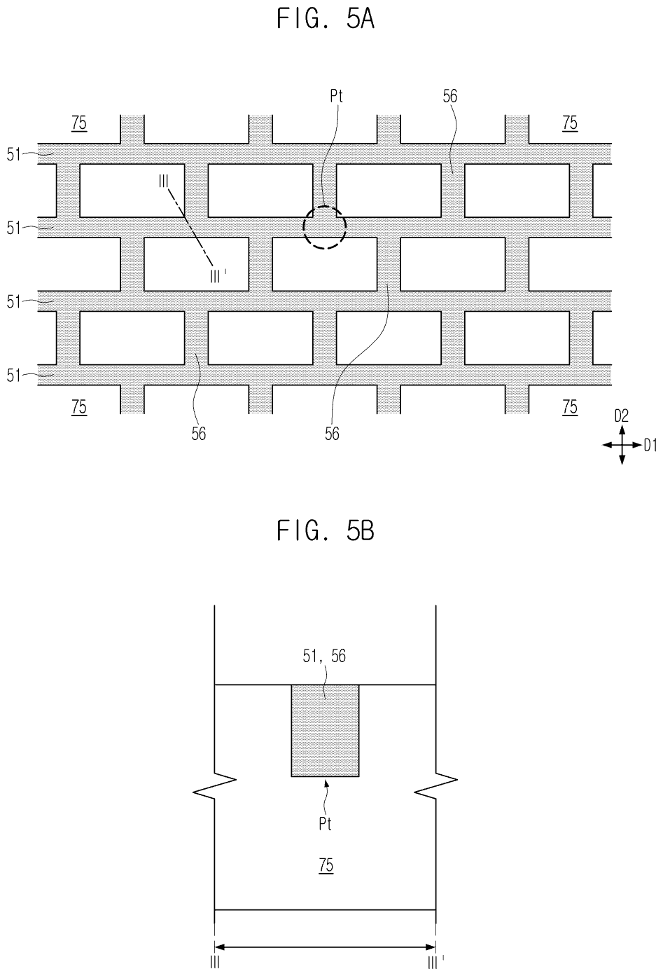

Referring to FIGS. 5A and 5B, the method may include forming interconnection patterns 51 and 56 by performing an additional deposition process and a planarization process. The interconnection patterns 51 and 56 may include line patterns 51 and segment patterns 56. The line patterns 51 may be formed in the first trenches 51t. The segment patterns 56 may be formed in the second trenches 56t.

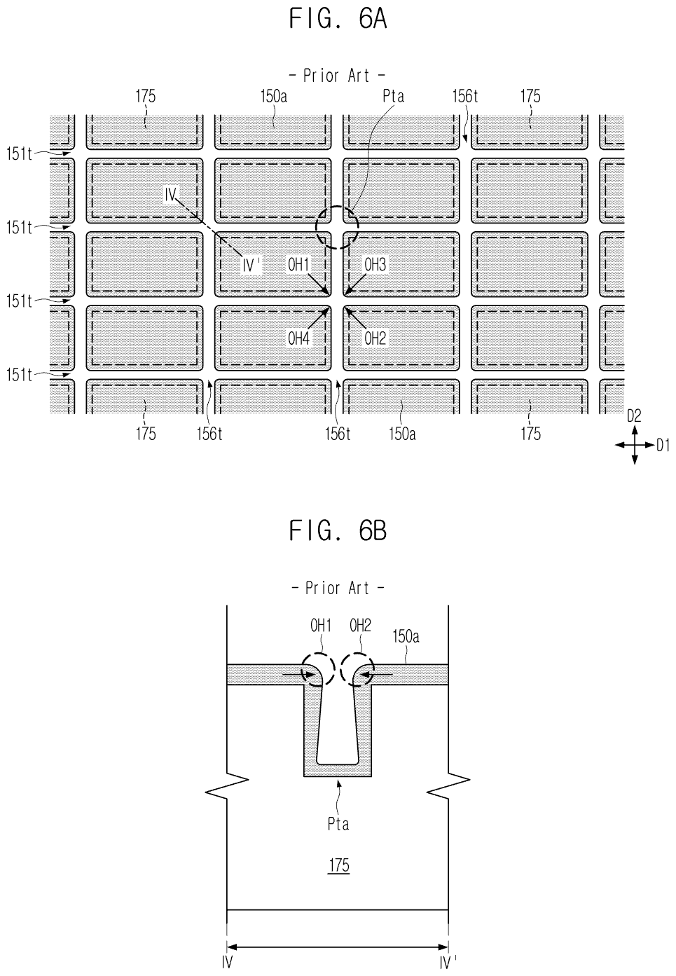

FIG. 6A is a plan view illustrating grid-type conventional trenches 151t and 156t formed by conventional technology, and FIG. 6B is a longitudinal cross-sectional view taken along the line IV-IV′ of FIG. 6A. The trenches 151t and 156t include first conventional trenches 151t and second conventional trenches 156t extending in parallel with each other in the first direction D1. Accordingly, a conventional trench connection points Pta are formed in a cross shape where the first and second conventional trenches 151t and 156t intersect with each other. When an interconnection material layer 150a is formed, overhangs OH1-OH4 may occur in the conventional trench branch points Pta. Specifically, the overhangs OH1-OH4 indicated with arrows occur at the four corners of the underlying layer 175 formed by conventional trenches 151t and 156t.

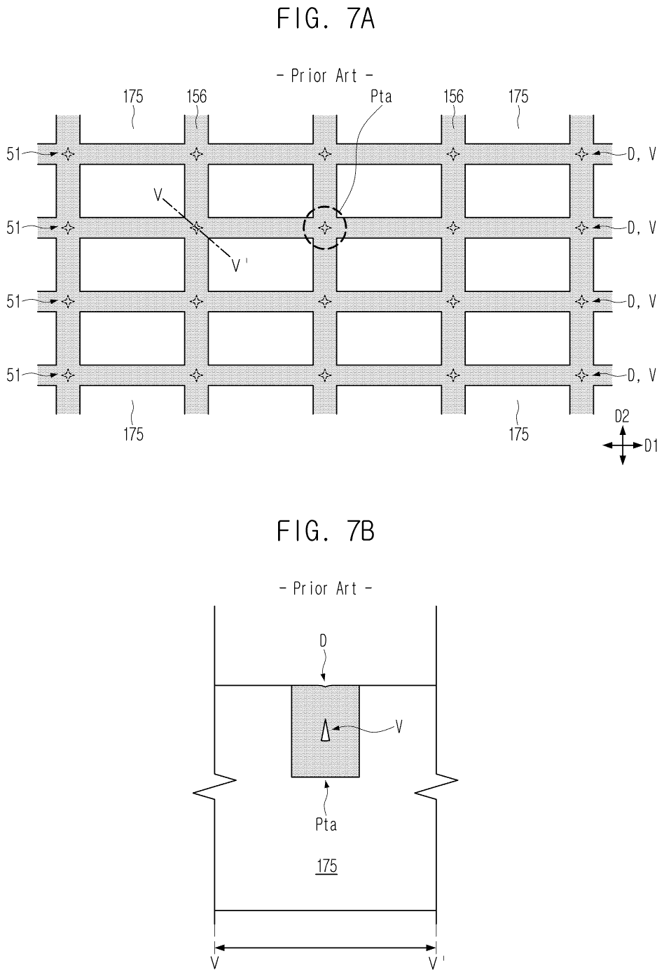

FIG. 7A is a plan view illustrating conventional interconnection patterns 151 and 156 formed by conventional technology, and FIG. 7B is a longitudinal cross-sectional view taken along the V-V′ line of FIG. 7A. Referring to FIGS. 7A and 7B, at trench connection points Pta, a void V or dent D occurs within or on the interconnection patterns 151 and 156. Due to the overhangs OH1-OH4 generated from the four corners, the conventional interconnection material layer 150a of FIGS. 6A and 6B does not sufficiently fill the center of the trench connection points Pta. Foreign substances such as organic materials or particles may remain in the dent D. The foreign substances remaining in the dent D may cause peeling of the material layers or corrosion of the metal layer. Additionally, the void V may cause more severe damage to the surrounding metal layer by expanding or contracting gas or liquid accumulated therein. In comparison, the interconnection patterns 51 and 56 according to the embodiment of the present disclosure shown in FIGS. 5A and 5B are insignificant enough to be negligible because the dent D and the void V are not formed or occur very finely.

According to the embodiments of the present disclosure, since the metal interconnection layer having reduced defect elements or negligible defect elements, stable power supply and electrical signal transmission can be achieved. Therefore, the semiconductor device can stably operate.

While the embodiments of the present disclosure have been described with respect to specific embodiments, it will be apparent to those skilled in the art that various changes and modifications may be made without departing from the spirit and scope of the present disclosure as defined in the following claims. Furthermore, the embodiments may be combined to form additional embodiments.

What is claimed is:

1. A semiconductor device comprising:
transistors disposed on a substrate; and
interconnection layers disposed over the transistors,
wherein the interconnection layer includes:
first patterns extending in parallel in a first direction; and
second patterns disposed between the first patterns, and connecting the first patterns to each other in a second direction perpendicular to the first direction,
wherein the second patterns are arranged spaced apart from each other in the first direction, and arranged in a zigzag shape in the second direction.

2. The semiconductor device of claim 1, wherein:
the first patterns include line-type patterns, and
the second patterns include segment-type patterns.

3. The semiconductor device of claim 1,
wherein two adjacent patterns of the first patterns and two adjacent patterns of the second patterns form one geometric pattern so that the first patterns and the second patterns form a plurality of geometric patterns, and
wherein the geometric patterns are aligned in the first direction and arranged parallel to each other.

4. The semiconductor device of claim 3,
wherein the geometric patterns and the reversed geometric patterns are alternately arranged in the first direction.

5. The semiconductor device of claim 4, wherein:
each of the geometric patterns includes a triangular or trapezoidal pattern, and
each of the reversed geometric patterns includes a reversed triangular pattern or a reversed trapezoidal pattern.

6. The semiconductor device of claim 3,
wherein the geometric patterns are offset arranged in the second direction.

7. The semiconductor device of claim 1,
wherein the upper interconnection layer includes connection points where one end of each of the second patterns contacts one side surface of each of the first patterns, and
wherein each of the connection points has a T-shape.

8. The semiconductor device of claim 1, further comprising:
third patterns connecting two of the second patterns adjacent to each other in the first direction.

9. The semiconductor device of claim 8,
wherein each of the third patterns has a segment shape that is elongated in the first direction.

10. The semiconductor device of claim 8,
wherein the third patterns are arranged spaced apart from each other in the first direction.

11. The semiconductor device of claim 8,
wherein the third patterns are arranged in a zigzag shape in the second direction.

12. The semiconductor device of claim 1,
wherein two of the second patterns form a pair of segment patterns, respectively, and
wherein the pairs of segment patterns have a mirrored shape to each other in the first direction.

13. The semiconductor device of claim 12,
wherein each of the pairs of segment patterns has an elongated shape in diagonal directions with respect to the first direction, respectively.

14. A semiconductor device comprising:
a lower interconnection layer including a plurality of lower interconnections;
a middle interconnection layer disposed on the lower interconnection layer, and including a plurality of middle interconnections; and
a power distribution network on the middle interconnection layer,
wherein the power distribution network includes:
a plurality of line patterns extending in parallel in a first direction; and
a plurality of first segment patterns having an elongated shape in a second direction perpendicular to the first direction,
wherein each of the first segment patterns contacts two of the line patterns adjacent in the second direction, and
wherein the first segment patterns are disposed spaced apart from each other in the first direction.

15. The semiconductor device of claim 14,
wherein two adjacent line patterns of the line patterns and two adjacent segment patterns of the first segment patterns form a geometric pattern so that the line patterns and the first segment patterns form a plurality of geometric patterns, and
wherein the geometric patterns are aligned in the first direction arranged side-by-side, and have an offset arrangement in the second direction.

16. The semiconductor device of claim 15,
wherein the geometric patterns and reversed geometric patterns are arranged alternately in the first direction.

17. The semiconductor device of claim 14,
wherein the power distribution network has a plurality of connection points on one side of the line patterns to which one end of the first segment patterns is in contact, and
wherein each of the plurality of connection points has a T-shape.

18. The semiconductor device of claim 14, further comprising:
second segment patterns connecting adjacent two of the first segment patterns to each other, and
wherein each of the second segment patterns has an elongated shape in the first direction.

19. The semiconductor device of claim 14,
wherein the line patterns and the first segment patterns are arranged to contact each other without crossing each other.

20. A semiconductor device comprising:
a plurality of line patterns extending in parallel in a first direction; and
a plurality of segment patterns between the plurality of line patterns, and connecting two adjacent line patterns of the line patterns to each other in a second direction,
wherein the first direction is perpendicular to the second direction,
wherein the plurality of line patterns and the plurality of segment patterns are arranged to form a plurality of geometric patterns so that two adjacent line patterns of the plurality of line patterns and two adjacent segment patterns of the plurality of segment patterns in the first direction form one geometric pattern,
wherein the geometric patterns are aligned in the first direction and arranged side-by-side, and
wherein the geometric patterns are arranged offset in the second direction.
